(19) United States
(12) Patent Application Publication
(10) Pub. No.: US 2018/0231603 A1
(43) Pub. Date: Aug. 16, 2018

(54) Systems and Methods for Detecting Occurence of an Event in a Household Environment

(71) Applicants: Abhay Gupta, Cupertino, CA (US); Vivek Garud, Los Altos, CA (US); Kalpit Desai, Mahadevapura (IN); Alex Shyr, Mountain View, CA (US); Abhishek Garg, Bangalore (IN)

(72) Inventors: Abhay Gupta, Cupertino, CA (US); Vivek Garud, Los Altos, CA (US); Kalpit Desai, Mahadevapura (IN); Alex Shyr, Mountain View, CA (US); Abhishek Garg, Bangalore (IN)

(21) Appl. No.: 15/898,060

(22) Filed: Feb. 15, 2018

Related U.S. Application Data
(60) Provisional application No. 62/459,463, filed on Feb. 15, 2017.

(51) Int. Cl. G01R 31/28; G01R 21/06

(52) U.S. Cl. CPC G01R 31/2825; G01R 21/06; G01R 31/2837

(57) ABSTRACT

The invention is directed to systems and methods for detecting occurrence of at least one event in a household environment. In one embodiment, the method includes receiving energy profile data determined for the household environment. The method may further include analyzing the energy profile data to obtain operation parameters for appliances being used in the household environment. The method may further include comparing the operation parameters with steady state parameters for each of the appliance based one or more deviation rules. The method may further include detecting occurrence of the at least one event in the household environment based on the comparing.

### RELATED APPLICATIONS

This application claims priority to U.S. Provisional Patent Application No. 62/459,463 filed on 15 Feb. 2017, the disclosure of which is incorporated herein by reference in its entirety.

### BACKGROUND

In general, the present invention is directed to efficient utilization of energy and more particularly to systems and methods for detecting occurrence of an event in a household environment based on energy consumption. In a household environment, various appliances are used to perform various operations. With over a period of time due to certain factors, the appliances may get faulty and start performing in an abnormal way. In such situations, it is vital to detect anomaly/defect in the appliances so that the appliances work properly in critical situations. For example, detecting anomaly in appliances used for health monitoring, additional security, and real-time alerts for fire hazard on time is very crucial so that these appliances work properly in case of any emergency. Furthermore, there are situations when an unexpected pattern may be observed in energy consumption. For example, an unexpected pattern may be detected in the case of a short circuit, power outage, or when nobody is at the home. In such cases, the power consumption may become almost negligible. Such patterns occurring in a household environment may be identified as events, which may in turn assist in efficiently utilizing energy by keeping users informed.

In the context of a household environment, detecting such events indicating a pattern in user behavior or anomaly in appliance energy usage either requires additional instrumentation, such as video surveillance systems, plug-level sensors for each appliance or requires regular examination, such services of appliances and machinery. Both the aforementioned techniques require additional resources and take lot of efforts to detect an anomaly in the appliances.

### SUMMARY

Aspects in accordance with some embodiments of the present invention may include a method for detecting occurrence of at least one event in a household environment. In one embodiment, the method comprises receiving energy profile data determined for the household environment; analyzing the energy profile data to obtain operation parameters for appliances being used in the household environment; comparing the operation parameters with steady state parameters for each of the appliance based one or more deviation rules; detecting occurrence of the at least one event in the household environment based on the comparing.

Some aspects in accordance with some embodiments of the present invention may include a system for detecting occurrence of at least one event in a household environment. The system comprises one or more hardware processors and a memory communicatively coupled to the one or more hardware processors storing instructions, that when executed by the one or more hardware processors, cause the one or more hardware processors to perform operations comprising receiving energy profile data determined for the household environment; analyzing the energy profile data to obtain operation parameters for appliances being used in the household environment; comparing the operation parameters with steady state parameters for each of the appliance based one or more deviation rules; detecting occurrence of the at least one event in the household environment based on the comparing.

Some aspects in accordance with some embodiments of the present invention may include a non-transitory computer readable medium for detecting occurrence of at least one event in a household environment. The computer readable medium stores instructions, that when executed by the one or more hardware processors, cause the one or more hardware processors to perform operations comprising receiving energy profile data determined for the household environment; analyzing the energy profile data to obtain operation parameters for appliances being used in the household environment; comparing the operation parameters with steady state parameters for each of the appliance based one or more deviation rules; detecting occurrence of the at least one event in the household environment based on the comparing.

It is to be understood that both the foregoing general description and the following detailed description are exemplary and explanatory only and are not restrictive of the invention, as claimed.

### BRIEF DESCRIPTION OF THE DRAWINGS

The present invention can be more fully understood by reading the following detailed description together with the accompanying drawings, in which like reference indicators are used to designate like elements. The accompanying figures depict certain illustrative embodiments and may aid in understanding the following detailed description. Before any embodiment of the invention is explained in detail, it is to be understood that the invention is not limited in its application to the details of construction and the arrangements of components set forth in the following description or illustrated in the drawings. The embodiments depicted are to be understood as exemplary and in no way limiting of the overall scope of the invention. Also, it is to be understood that the phraseology and terminology used herein is for the purpose of description and should not be regarded as limiting. The detailed description will make reference to the following figures, in which:

FIG. 1 illustrates an exemplary system for detecting occurrence of an event in a household environment, in accordance with some embodiments of the present disclosure.

FIG. 2 illustrates an exemplary method for detecting occurrence of an event in a household environment, in accordance with some embodiments of the present disclosure.

Before any embodiment of the invention is explained in detail, it is to be understood that the present invention is not limited in its application to the details of construction and the arrangements of components set forth in the following description or illustrated in the drawings. The present invention is capable of other embodiments and of being practiced or being carried out in various ways. Also, it is to be understood that the phraseology and terminology used herein is for the purpose of description and should not be regarded as limiting.

### DETAILED DESCRIPTION

The matters exemplified in this description are provided to assist in a comprehensive understanding of various exemplary embodiments disclosed with reference to the accompanying figures. Accordingly, those of ordinary skill in the art will recognize that various changes and modifications of the exemplary embodiments described herein can be made without departing from the spirit and scope of the claimed invention. Descriptions of well-known functions and constructions are omitted for clarity and conciseness. In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood, however that it is not intended to limit the disclosure to the particular forms disclosed, but on the contrary, the disclosure is to cover all modifications, equivalents, and alternative falling within the scope of the disclosure.

The terms “comprises”, “comprising”, or any other variations thereof, are intended to cover a non-exclusive inclusion, such that a setup, device or method that comprises a list of components or steps does not include only those components or steps but may include other components or steps not expressly listed or inherent to such setup or device or method. In other words, one or more elements in a system or apparatus proceeded by “comprises . . . a” does not, without more constraints, preclude the existence of other elements or additional elements in the system or apparatus.

In the following detailed description of the embodiments of the disclosure, reference is made to the accompanying drawings that form a part hereof, and in which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

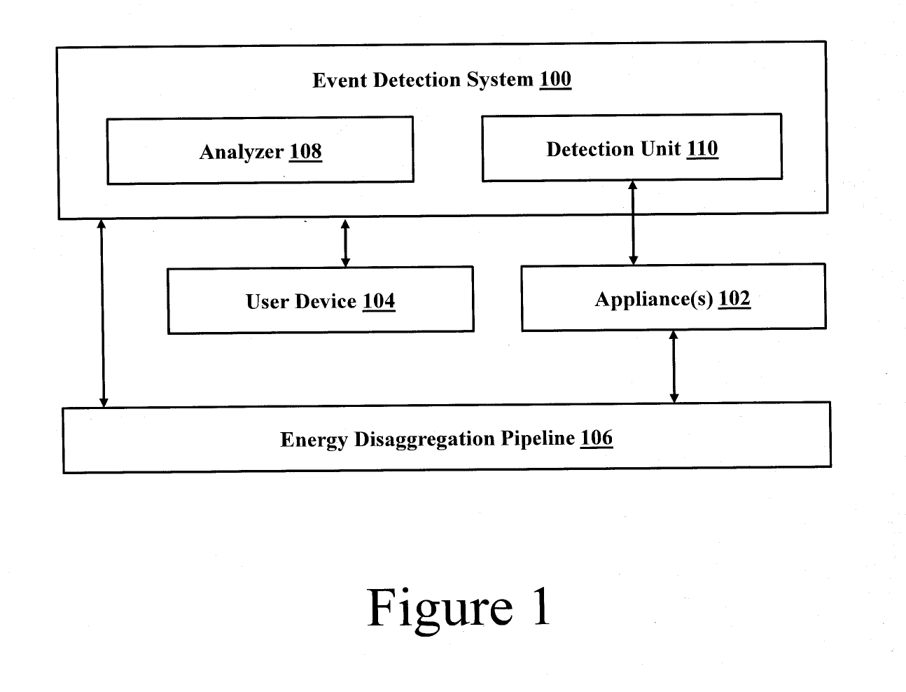

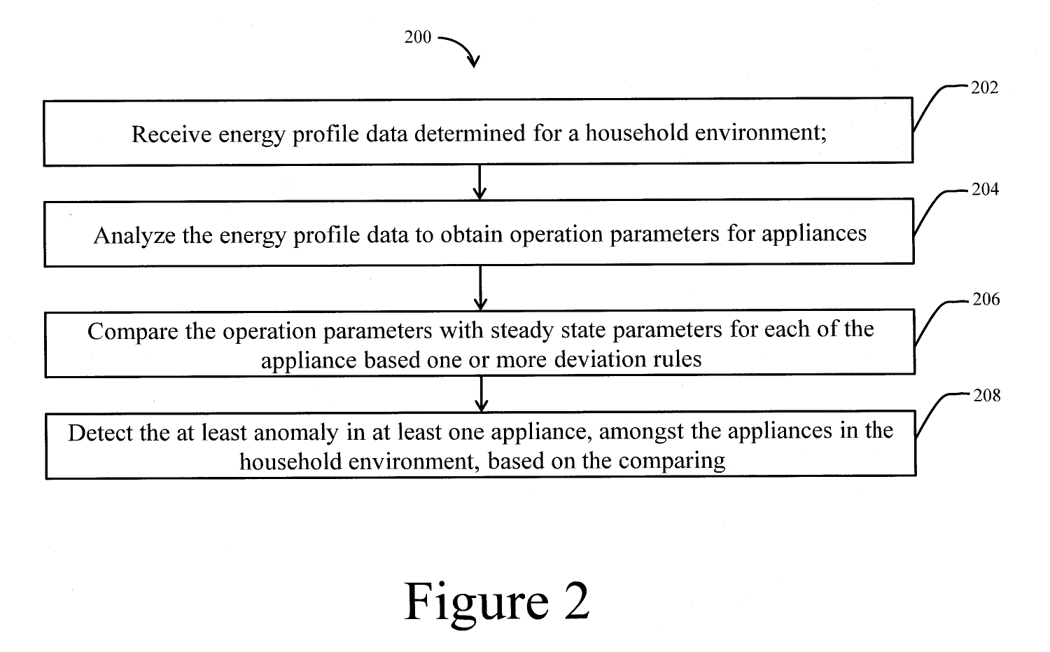

The present subject matter for detecting anomaly in appliances present in a household environment, in accordance with the present subject matter, is described in detail in conjunction with FIGS. 1-2. It should be noted that the description and drawings merely illustrate the principles of the present subject matter. It will thus be appreciated that those skilled in the art will be able to devise various arrangements that, although not explicitly described or shown herein, embody the principles of the present subject matter and are included within its spirit and scope. While aspects of the platform and method can be implemented in any number of different environments, and/or configurations, the embodiments are described in the context of the following exemplary system architecture(s).

Note that in the past, event detection typically required physical sensors or monitors that were located proximate to devices, appliances, and/or homes. The present invention improves this technology to provide a system and method for detecting events based upon energy usage patterns. This improvement—which creates a more accurate, faster, and adaptable system (adaptable since appliances can be added to the home without the need to provide updated local sensors or monitors), provides customers and utilities alike with advanced and actionable information and determinations.

FIG. 1 illustrates an exemplary event detection system 100 for detecting occurrence of an event in a household environment, in accordance with some embodiments of the present disclosure. An event may be understood as a scenario when an unexpected user behavior is observed or when there is an anomaly or irregularity in functioning of appliances 102. For brevity, hereinafter the event detection system 100 may be referred to as system 100.

As shown in FIG. 1, system 100 is communicatively coupled to the appliances 102 and a user device 104. The appliances 102 may be a device used in a household or a commercial environment, such as an emergency warning system, a healthcare monitoring system, a surveillance system, a pool pump, and an air conditioning system. The appliances 102 in the household environment consume power and same is recorded by an energy meter. When there is an anomaly/irregularity in functioning of the appliances 102, the system monitors an energy pattern of appliances and detects the anomaly in the appliances 102. It may be noted that, hereinafter, the appliances 102 may be individually referred to as an appliance 102.

The user device 104 may be a handheld device used by a user. The user device 104 may be used for alerting the user in case occurrence of an event is detected indicating of anomaly detection in one of the appliances 102. In an example, the user devices 104 may be an alert system used by fire stations. In case of a short circuit, the alert system may be notified by the system 100. In another example, the user device 104 may be a device used by relatives and/or friends of the user. In case of long power outage and when user is not around, the system 100 may alert relatives and/or friends about the event. In another example, the system 100 may alert law enforcement in case the user has specified that he will be away for a duration and an unexpected pattern in obtained in the energy consumption during that duration.

Further, the system 100 is communicatively coupled to the energy disaggregation pipeline 106. The system 100 may communicate with the energy disaggregation pipeline 106 to obtain energy disaggregation data of the appliances 102 and provide anomaly detection feedback. In an example, the energy disaggregation pipeline 106 may be fed with information such as, but not limited to, weather information, user location details, and appliance data so that an informed decision may be made by the system 100 before alerting users about the occurrence of the event.

As shown in FIG. 1, the system 100 comprises an analyzer 108 and a detection unit 110. In operations, to detect occurrence of an event indicating deviation in user behavior, deviation from an expected pattern, or an anomaly/irregularity in functioning of the appliances 102, the analyzer 108 may receive energy profile data from energy meters configured to measure power consumption of the appliances 102 present in the household environment. When the appliances 102 perform certain operations, they consume power that is recorded by the energy meters. The analyzer 108 communicates with the energy meters and obtains the energy profile data of the appliances 102 which are being used in the household environment. In an example, the energy profile data may comprise power consumption reading and patterns of the appliances. In another example, the energy profile data may also include appliance-plug-level sensor data.

Once the energy profile data is obtained, the analyzer 108 may analyze the energy profile data to generate disaggregated energy data associated with the appliances 102 being used in the household environment. The disaggregated energy data may indicate energy consumption pattern of each of the appliances 102 being used. Thereafter, the analyzer 108 may analyze the disaggregated energy data to obtain operation parameters for each of the appliances. Examples of the operation parameters may include power drawn, power outage, zero reading, input/output state of the household environment, current drawn, and running time of the appliances. It may be noted that the operation parameters provided here exemplary and other operation parameters may also be used without deviating from scope of the present subject matter.

In another example, the analyzer 108 may directly obtain the operation parameters by analyzing the energy profile data without generating the energy disaggregation data. The analyzer 108 may apply one or more predefined rules to the energy profile data to obtain the operation parameters.

Upon obtaining the operation parameters, the detection unit 110 may obtain steady state parameters for each of the appliances 102 from a repository. In an example, the steady state parameters may indicate values of the operation parameters in a steady state of the appliances 102. Subsequently, the detection unit 110 may compare the operation parameters with the steady state parameters based one or more deviation rules. In an example, the one or more deviation rules may comprise change in power consumption rule, zero-power reading rule, power outage, short circuits, pattern of usage, and duration of usage rule and comparison to trends of the same operation parameter in other similar homes.

Further, if any deviation is detected in any of the appliances 102 based on the comparison, that particular appliance is identified as faulty or an appliance with the anomaly. Then, the anomaly along with details of the appliance 102 is provided to the user. Further, if deviation from an expected pattern is detected, then the notification may identify such deviation as an event and notify the user. In an example, the detection unit 110 may send a notification to the user device 104 indicating the appliances 102 with the anomaly. In this manner, the system 100 detects occurrence of the event indicating anomaly in the appliances 102 or deviation in functioning without using additional resources, such as sensors and reports it to the user with various insights. The insights may be then used by the user in instructing the system 100 to take corrective action.

Some of use case examples are listed below to explain functioning of the system in detecting anomalies in the appliances 102.

In an example, to detect anomaly in an appliance used to detect water level in a swimming pool, the system 100 may monitor undulations in power drawn of a pool pump (in HAN) or lower-than-usual average power (in GB). If the power drawn is less than a predefined threshold value, the system 100 may alert the user about low level of water in the swimming pool.

In another use case example, to detect anomaly in operations of a pool pump, the system 100 may identify a change in normal operation of the pool pump by looking for consistency of amplitude but change in time-of-day operation schedule. Upon detecting an abnormal pattern, the system 100 may alert the user about the same. For example, the system 100 may alert the user about a change in pool pump operation, such as new schedule, turned off, and malfunctioning. In another example, the system 100 may alert the user about unusually fast creep in pool pump timer clock.

In another use case example, where a vacant home vigilance system that monitors a vacant home for breach, short-circuits etc. is used, the user may activate a feature by specifying that the home would be vacant from day X to Y. The vacant home vigilance system models “vacant” patterns from the historic data (e.g. weekday nights). Starting from the day X, the system 100 may monitors the streaming power demand signal in near real-time. An alarm is produced by the system 100 when the power-draw rises above a pre-learned home-specific threshold or when a pattern sufficiently far from “vacant” pattern is detected. Further, the system 100 may notify the user through a mobile application, when someone comes home after a prolonged period of inactivity. The system 100 may consider statistical “change-point” after a prolonged period of regular pattern in the whole-house consumption signal. The system 100 may also monitor consumption pattern at night times over a few weeks of data to build statistical model of what “inactivity” looks like in a given home, and then identify it as activity a stretch of the signal that doesn't match the inactivity model.

In another use case example, the system 100 may notifying the user about appliances 102 that seem to be running for too long, or seems left running in a home that looks vacant. The system 100 may monitor oven to avoid fire hazard, Air Conditioner (AC) to avoid energy wastage, and heating devices to avoid fire hazard and energy wastage.

In another use case example, the system 100 may identify and alert the user about prolonged power outage based on zero-reading/discontinuity in power demand curve. This may be helpful in determining whether user needs to trigger back-up generator (e.g. to preserve items in fridge etc.).

Thus, the present invention detects occurrence of the event indicating anomaly in the appliances or deviation from functioning defined by the user in an efficient manner without using additional resources. Also, the present subject matter alerts end-consumers of energy by using the data that is already being collected by whole-premise energy meters, without needing additional sensors. Such ability of the present subject matter will help energy distribution companies in engaging with their customers in a better way, which could in turn improve customer retention, efficacy of demand reduction programs etc. Further, the present subject matter also enables the user to become more energy efficient, learn about appliance malfunctions early on, and stay alerted about safety/security hazards in near real time etc.

Specific types of events are set forth below. Events that may be detected by the system 100 may include, but are not limited to, events related to refrigeration, water heaters, HVAC systems, electric vehicles, solar, lighting, events related to baseload, and/or events related to overall lifestyle usage.

Refrigeration. The system 100 may identify in case of refrigeration that the cycle frequency or peak amplitude has changed from the standard values. This may mean that refrigerator is not working properly and alert user to get the refrigerator checked to make sure items are preserved in the refrigerator. The system 100 may similarly identify that the refrigeration signal has stop cycling and instead of having similar pattern after a standard duration the signal only has a flat line. This may mean that door of the refrigerator might be left open my mistake. The system can then alert the user to avoid energy wastage and make sure items in refrigerator are preserved.

Water Heater. The system 100 may identify a change in the normal operations of water heater by looking for consistency in amplitude and frequency of the signal but change in the schedule of operation. Upon detecting such anomaly the system can report this to the consumer. For example, the system can report that the water heater usage is falling under different rate plans. At Least one rate can be higher than the other. User can use this information to set a schedule which is the cheapest one for him.) The system 100 can detect that water heater which was previously working on a particular schedule has stopped operating on a timer. Alerting the user will allow him to confirm if this is intended and if not select the cheapest schedule.

The system 100 may similarly detect a discontinuity in the power signal and then a schedule change in water heater. This may mean that timer of the water heater is not on its schedule because of reasons such as a power outage. This may lead to energy wastage as water heater is not intended to run at that time and also user might be paying more money as the new schedule might be on expensive tariff. Hence alerting user can save both energy and money.

HVAC. The system 100 can identify in case of HVAC that the setpoint of the appliance has been changed. The system can then alert the user to confirm if the change was intentional or it was changed because of some issue in the HVAC appliance or the thermostat. Fixing such unintentional changes in setpoint can help in avoiding energy wastage and save electricity for the user.

Similarly, the system 100 may identify changes in the normal operation of HVAC by looking for consistency in the set point of HVAC but changes in the schedule of HVAC. Usually the HVAC runs on particular schedule. The system 100 may alert the user about changes in HVAC operations, such as different schedule, HVAC is turned off for long time or it is malfunctioning as with a particular set-point the HVAC should start and stop on a standard time.

The system 100 may also identify changes in power drawn by HVAC and report this as anomaly as this may indicate that the appliance is not working properly and the premise is not getting heated/cooled properly. The anomaly can be detected using indoor and/or outdoor temperature information as well as possible comparison with HVAC usage trends in the neighborhood homes.

Electric Vehicles. The system 100 may be able to identify an anomaly as new installation of an Electric Vehicle in a home and then alert the user to check if the installation is intentional and also alert the user about the estimated time taken to charge the vehicle. The user can then confirm if the information is correct and or not.

The system 100 may also detect change in normal operations of charging of Electric Vehicle by looking for consistency in the amplitude of signal but change in the time-of-day operation schedule. If an abnormal pattern is detected, the system 100 may then alert the user about the same. For example the EV might be getting charged on a expensive rate plan which can result in higher bill for a user.

Solar. The system 100 may detect anomaly in solar detection by monitoring the energy generated by the panel. If the system 100 detects degradation in solar generation, the system may check if the degradation is gradual or sudden by comparing it with the generation from previous month and previous year. The system can also use the weather data available for the location like sunrise sunset time, cloud cover and precipitation to estimate if the decrease is under standard threshold. If the degradation is not under standard threshold, the system 100 can alert the user to check the panels which may have layer of dust or debris or shade from nearby trees/structures over the panels.

Lighting. The system 100 may identify the running time of the lights in the house. The system 100 can detect an anomaly for example that the lights are switched on throughout the night. If this has been a recent change then the user can be alerted for the same. This can enable the user to check lights in his house and switch off the faulty lights. The anomaly detection can help to save energy and money. The system 100 may also detect that the lights are switched on for a longer duration or during the day time. This can be reported to user so that he can take preventive actions.

Base Load. The system 100 continuously monitors the baseload of the home and can detect anomaly if a change in baseload power usage is observed. The system may also compare the user to houses which are similar to the user's house based on parameters like similar geography, similar house type, similar number of people living in house etc. The above mentioned parameters to determine similar house is not an exhaustive list and other parameters can be added to determine similar house. The system can check if users base load consumption is similar to similar homes and also constantly monitors if there are any changes in the consumption pattern of base load and other appliances compared to similar homes. If any anomaly is observed, the system 100 can alert the user so that user can check if there are any appliances which are always running unintentionally and stop running those to save energy. Also the user can filter out any inefficient appliance and replace them with energy efficient appliances.

Lifestyle. The system 100 may even detect lifestyle changes such as work schedule changes, longer or shorter working hours, amount of sleep time, activity during weekdays/weekends, holidays and vacations.

FIG. 2 illustrates an exemplary method for detecting occurrence of an event in a household environment, in accordance with some embodiments of the present disclosure.

The method 200 may be described in the general context of computer executable instructions. Generally, computer executable instructions can include routines, programs, objects, components, data structures, procedures, modules, and functions, which perform particular functions or implement particular abstract data types. The method 200 may also be practiced in a distributed computing environment where functions are performed by remote processing devices that are linked through a communication network. In a distributed computing environment, computer executable instructions may be located in both local and remote computer storage media, including memory storage devices.

The order in which the method 200 described is not intended to be construed as a limitation, and any number of the described method blocks can be combined in any order to implement the method 200 or alternative methods. Additionally, individual blocks may be deleted from the method 200 without departing from the spirit and scope of the subject matter described herein. Furthermore, the method 200 can be implemented in any suitable hardware, software, firmware, or combination thereof.

With reference to method 200 as depicted in FIG. 2, at block 202, energy profile data determined for a household environment is received. The energy profile data may comprise power consumption reading and patterns of the appliances 102 that are being used in the household environment. In an example, the analyzer 108 may receive the energy profile data from energy meters installed in the household environment.

At block 204, the energy profile data is analyzed to obtain operation parameters for the appliances 102 being used in the environment. Examples of the operation parameters may include power drawn, power outage, zero reading, input/output state of the household environment, current drawn, and/or running time of the appliances. In an example, the analyzer 108 may analyze the energy profile data to obtain the disaggregated energy data. The disaggregated energy data may indicate energy consumption pattern of each of the appliances 102 being used in the household environment. The disaggregated energy data may help the system 102 in identifying an anomaly/irregularity in the appliances 102 as it provides the energy consumption pattern of each of the appliances 102 separately. The disaggregated energy data is analyzed to obtain operation parameters for each of the appliances. In an example, the analyzer 108 may analyze the disaggregated energy data to obtain the operation parameters.

At block 206, the operation parameters are compared with steady state parameters for each of the appliance. In an example, the detection unit 110 may obtain the steady state parameters for each of the appliances 102 from a repository. In an example, the steady state parameters indicate values of the operation parameters in a steady state of the appliances 102. Once the steady state parameters are obtained, the detection unit 110 may compare the operation parameters with the steady state parameters based one or more deviation rules. The one or more deviation rules may comprises change in power consumption rule, zero-power reading rule, power outage, short circuits, pattern of usage, and duration of usage rule. It may be noted that that one or more deviation rules listed here are exemplary. More deviation rules may be specified depending upon the use case and user preferences without deviating from scope of the present subject matter.

At block 208, occurrence of the event indicating a deviation in functioning or an anomaly in an appliance is detected in the household environment based on the comparing. In an example, the detection unit 110 may detect the occurrence of the event indicating an anomaly in the appliance 102 or deviation in operations specified by the user based on the comparison between the operation parameters and the steady state parameters. Further, the detection unit 110 may send a notification to a user device indicating the occurrence of the event.

In this manner, occurrence the event is detected in the household environment without using additional resources, such as sensor. Further, the user is alerted with various notifications having anomaly details and insights which could be used further in improving performance of the appliances 102 in the home environment.

It may be noted that the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

It is intended that the disclosure and examples be considered as exemplary only, with a true scope and spirit of disclosed embodiments being indicated by the following claims.

What is claimed is:

1. An event detection system to detect occurrence of at least one event in a household environment, wherein the event detection system comprising:
a hardware processor; and
a memory storing instructions executable by the hardware to perform operations comprising:
receiving energy profile data determined for the household environment;
analyzing the energy profile data to obtain operation parameters for appliances being used in the household environment;
comparing the operation parameters with steady state parameters for each of the appliance based one or more deviation rules, wherein the steady state parameters indicate values of the operation parameters in a steady state of the appliances; and
detecting occurrence of the at least one event in the household environment based on the comparing.

2. The event detection system of claim 1, wherein operations further comprising sending a notification to a user device indicating occurrence of the at least one event, wherein the notification comprises at least one of details of event and anomaly in the appliances present in the household environment

3. The event detection system of claim 1, wherein the energy profile data comprises power consumption reading and patterns of the appliances.

4. The event detection system of claim 1, wherein the operation parameters comprise at least one of power drawn, power outage, zero reading, input/output state of the household environment, current drawn, running time, and schedule of the appliances.

5. The event detection system of claim 1, wherein the one or more deviation rules comprises at least one of change in power consumption rule, zero-power reading rule, power outage, short circuits, pattern of usage, duration of usage rule, and comparison to trends of a matching operation parameter in other similar homes.

6. The event detection system of claim 1, wherein the operation parameters are obtained by:
analyzing the energy profile data to generate disaggregated energy data associated with the appliances being used in the household environment; and
analyzing the disaggregated energy data to obtain the operation parameters for each of the appliances.

7. A method for detecting occurrence of at least one event in a household environment, the method comprising:
receiving, by an event detection system, energy profile data determined for the household environment;
analyzing, by the event detection system, the energy profile data to obtain operation parameters for appliances being used in the household environment;
comparing, by the event detection system, the operation parameters with steady state parameters for each of the appliance based one or more deviation rules, wherein the steady state parameters indicate values of the operation parameters in a steady state of the appliances; and
detecting, by the event detection system, occurrence of the at least one event in the household environment based on the comparing.

8. The method as claimed in claim 7 further comprises sending, by the anomaly detection data, a notification to a user device indicating occurrence of the at least one event, wherein the notification comprises at least one of details of event and anomaly in the appliances present in the household environment.

9. The method as claimed in claim 7, wherein the energy profile data comprises power consumption reading and patterns of the appliances.

10. The method as claimed in claim 7, wherein the operation parameters comprise at least one of power drawn, power outage, zero reading, input/output state of the household environment, current drawn, running time, and schedule of the appliances.

11. The method as claimed in claim 7, wherein the one or more deviation rules comprises at least one of change in power consumption rule, zero-power reading rule, power outage, short circuits, pattern of usage, duration of usage rule, and comparison to trends of a matching operation parameter in other similar homes.

12. The method as claimed in claim 7, wherein analyzing the energy profile data further comprises:
analyzing the energy profile data to generate disaggregated energy data associated with the appliances being used in the household environment; and
analyzing the disaggregated energy data to obtain the operation parameters for each of the appliances.

13. A non-transitory computer readable medium storing instructions for detecting occurrence of at least one event in a household environment, that when executed by the one or more hardware processors, causes the one or more hardware processors to perform operations comprising:
receiving energy profile data determined for the household environment;
analyzing the energy profile data to obtain operation parameters for appliances being used in the household environment;
comparing the operation parameters with steady state parameters for each of the appliance based one or more deviation rules, wherein the steady state parameters indicate values of the operation parameters in a steady state of the appliances; and
detecting occurrence of the at least one event in the household environment based on the comparing.

14. The non-transitory computer readable medium of claim 13, wherein the operations further comprising sending a notification to a user device indicating occurrence of the at least one event, wherein the notification comprises at least one of details of event and anomaly in the appliances present in the household environment.

15. The non-transitory computer readable medium of claim 13, the energy profile data comprises power consumption reading and patterns of the appliances.

16. The non-transitory computer readable medium of claim 13, wherein the operation parameters comprise at least one of power drawn, power outage, zero reading, input/output state of the household environment, current drawn, running time, and schedule of the appliances.

17. The non-transitory computer readable medium of claim 13, wherein the one or more deviation rules comprises at least one of change in power consumption rule, zero-power reading rule, power outage, short circuits, pattern of usage, duration of usage rule, and comparison to trends of a matching operation parameter in other similar homes.

18. The non-transitory computer readable medium of claim 13, wherein the operation parameters are obtained by:
analyzing the energy profile data to generate disaggregated energy data associated with the appliances being used in the household environment; and
analyzing the disaggregated energy data to obtain the operation parameters for each of the appliances.
